(19) United States
(12) Patent Application Publication
(10) Pub. No.: US 2025/0379036 A1
(43) Pub. Date: Dec. 11, 2025

(54) ASYMMETRIC TRANSMISSION CIRCULAR WAVEGUIDE AND MICROWAVE PLASMA EXCITATION DEVICE

(71) Applicant: Chengdu University of Technology, Chengdu City (CN)

(72) Inventors: Fengming Yang, Chengdu City (CN); Yuanyuan Wu, Chengdu City (CN)

(73) Assignee: Chengdu University of Technology, Chengdu City (CN)

(21) Appl. No.: 18/983,526

(22) Filed: Dec. 17, 2024

(30) Foreign Application Priority Data
Jun. 7, 2024 (CN) 202410737456.X

(51) Int. Cl. H01J 37/32

(52) U.S. Cl. CPC H01J 37/32229

(57) ABSTRACT

Provided are an asymmetric transmission circular waveguide and a microwave plasma excitation device, including a cylindrical outer housing and a lining medium installed within the outer housing. The wall thickness of the lining medium gradually varies along the axial direction. Microwave energy transmits unidirectionally, only from the end of the lining medium with the thinnest wall thickness to the end with the thickest wall thickness, and cannot be fed in or transmitted from the opposite end of the asymmetric structure. By modifying the structure of the lining medium material within the waveguide, the volume ratio of the lossless dielectric material to air is controlled to approximate a gradual change in relative dielectric constant, improving the microwave energy utilization efficiency of the microwave plasma device. This microwave plasma excitation device can excite argon plasma within a pressure range of 0.1 torr to 10 torr while maintaining high energy efficiency.

### CROSS-REFERENCE TO RELATED APPLICATION

This patent application claims the benefit and priority of Chinese Patent Application No. 202410737456.X filed with the China National Intellectual Property Administration on Jun. 7, 2024, the disclosure of which is incorporated by reference herein in its entirety as part of the present application

### TECHNICAL FIELD

The present disclosure relates to the technical field of plasma excitation devices, and more specifically relates to the technical fields of asymmetric transmission circular waveguides, and microwave plasma excitation devices.

### BACKGROUND

With the more and more extensive application of plasma in daily life, the demand for various plasma sources is more urgent. The common plasma sources are direct-current high voltage, radio frequency, microwaves, etc. Microwave plasma is characterized by high particle activity, high plasma density, and low self-bias, making it widely applicable in the field of material processing.

Most of the existing plasma excitation technologies improve microwave energy utilization rate by designing impedance matching or focusing the electric field.

Electromagnetic wave resonance is often employed to enhance electric field intensity, facilitating easier plasma excitation. The microwaves, after entering the resonant cavity, are reflected in the resonant cavity to form standing waves, making the microwave energy strengthened. The high electric field intensity generated by the resonant cavity is used to break through the gas to generate plasma, and the distribution of standing waves is adjusted by adjusting the short-circuit piston at the bottom of the resonant cavity.

The research of improving the electric field intensity in the cavity by generating plasma using waveguide coupled microwave is becoming more and more common. The electric field intensity is increased by using dual-port microwave input of waveguide and adding metal diaphragm to gather electric field. Meanwhile, the electromagnetic field can be concentrated by using a gradient waveguide or a step waveguide, and optimizing nozzle structure, optimizing airflow, width and height of a coupling probe and a coupling waveguide, thus improving the energy utilization rate.

Discontinuous linear plasma can be obtained by introducing discontinuous slots in a parallel waveguide, and the microwave energy utilization rate can be improved by reasonably selecting the length of waveguide compression part. By developing metamaterial array structure, a large-area discontinuous plasma array can be directly generated under low pressure by microwave radiation.

Since plasma is a complex, time-varying system, changes in process parameters such as temperature, gas type, gas flow rate, or alterations in cavity structure can all affect the plasma state. Consequently, achieving efficient microwave-to-plasma energy conversion for different plasma conditions is challenging. Additionally, the complexity of some device structures hinders their application in large-scale plasma processing.

### SUMMARY

An objective of the present disclosure is that in order to solve the technical problems of low efficiency and complex structure of the existing microwave plasma excitation device, an asymmetric transmission circular waveguide and a microwave plasma excitation device are provided in the present disclosure.

To achieve the objective above, the following technical solutions are employed in the present disclosure:

In one aspect of the present disclosure, an asymmetric transmission circular waveguide is provided in the present disclosure, which includes a cylindrical outer housing, and a lining medium sleeved in the outer housing. A wall thickness of the lining medium gradually changes in an axial direction, one end of the lining medium with a thinnest wall thickness is a microwave feed port, and another end of the lining medium with a thickest wall thickness is a scattering boundary. Microwave energy is transmitted unidirectionally in a direction from the end of the lining medium with the thinnest wall thickness to the other end of the lining medium with the thickest wall thickness.

In an embodiment, the lining medium is formed by rotating a wedge-shaped structure around a center thereof.

In an embodiment, the feed port of the lining medium with the thinnest wall thickness is provided with a coupling waveguide.

In an embodiment, both ends of the outer housing are respectively in alignment with both ends of the lining medium, the coupling waveguide is fixedly arranged on the outer housing near the feed port of the lining medium, and the coupling waveguide is in communication with the feed port of the lining medium.

In an embodiment, the outer housing and the lining medium each have a length of 260 mm, and the coupling waveguide has a length of 30 mm.

In an embodiment, the lining medium is made of a lossless dielectric material with a relative dielectric constant of 25.

In another aspect of the present disclosure, a microwave plasma excitation device based on an asymmetric transmission circular waveguide is provided, including the above-mentioned asymmetric transmission circular waveguide, and further including a cylindrical cavity body which is arranged on one side of a scattering boundary of a lining medium and in mutual communication with the lining medium. The cylindrical cavity body is internally provided with a cylindrical tube for accommodating plasma.

In an embodiment, the cylindrical cavity body is made of a lossless dielectric material with a relative dielectric constant of 20, and the cylindrical tube is made of a lossless dielectric material with a relative dielectric constant of 9.

In an embodiment, one end of the cylindrical tube is in alignment with a tail end of the outer housing.

In an embodiment, the outer housing is made of metal, and a tube wall of the cylindrical tube and a tube wall of the cylindrical cavity body are made of ceramics.

The present disclosure has the beneficial effects that:

By modifying the volume ratio of a lossless dielectric to air within the waveguide, a continuous variation in the dielectric constant along the electromagnetic wave propagation direction is realized, enabling asymmetric microwave transmission in the circular waveguide. This design enhances the microwave energy utilization efficiency of the microwave plasma device. The device is characterized by its versatility under various air pressure conditions, simplicity in structure, and ease of implementation.

### BRIEF DESCRIPTION OF THE DRAWINGS

FIG. 1 is a schematic structural diagram of an asymmetric transmission circular waveguide according to the present disclosure, in which FIG. 1A is a perspective view of the asymmetric transmission circular waveguide, FIG. 1B is a cross-sectional view of forward transmission of the asymmetric transmission circular waveguide, and FIG. 1C is a cross-sectional view of reverse transmission of the asymmetric transmission circular waveguide;

FIG. 2 illustrates an ideal metamaterial with a gradually varying dielectric constant and its equivalent replacement structure, FIG. 2A shows the ideal metamaterial structure, where the dielectric constant gradually increases along the positive x-axis, FIG. 2B depicts a wedge-shaped structure designed to replace the ideal metamaterial; where the air volume fraction progressively decreases along the positive x-axis, effectively resulting in a gradual increase in the dielectric constant within the region;

FIG. 3 is an equipotential diagram of the electric field distribution in an asymmetric transmission circular waveguide, wherein FIG. 3A shows the equipotential lines of the electric field for forward transmission, and FIG. 3B shows the equipotential lines of the electric field for reverse transmission; the electric field distributions for forward and reverse transmissions exhibit significant asymmetry;

FIG. 4 is a schematic structural diagram of a microwave plasma excitation device based on an asymmetric transmission circular waveguide, in which FIG. 4A is a perspective structural diagram, and FIG. 4B is a cross-sectional structural diagram;

FIG. 5 shows equipotential diagrams of electron density distribution at different pressures, in which FIG. 5A shows the equipotential diagram of electron density at the pressure of 0.1 torr, FIG. 5B shows the equipotential diagram of electron density at the pressure of 1 torr, and FIG. 5C shows the equipotential diagram of electron density at the pressure of 10 torr, the electron density values indicate that the plasma has been effectively excited;

FIG. 6 shows equipotential diagrams of the electric field distribution at different pressures, in which FIG. 6A shows an equipotential diagram of the electric field distribution at the pressure of 0.1 torr, FIG. 6B shows an equipotential diagram of the electric field distribution at the pressure of 1 torr, and FIG. 6C shows an equipotential diagram of the electric field distribution at the pressure of 10 torr;

Reference numerals in the drawings: 1—lining medium; 2—cylindrical cavity body; 3—cylindrical tube.

### DETAILED DESCRIPTION OF THE EMBODIMENTS

To make the objectives, technical solutions and advantages of the embodiments of the present disclosure more clearly, the following clearly and completely describes the technical solutions in the embodiments of the present disclosure with reference to the accompanying drawings in the embodiments of the present disclosure. The described embodiments are merely a part rather than all of the embodiments of the present disclosure. The components in the embodiments of the present disclosure generally described and illustrated in the accompanying drawings herein can be arranged and designed in a variety of different configurations.

The following detailed description of the embodiments of the present disclosure provided in the accompanying drawings is not intended to limit the claimed scope of the present disclosure, but merely represents selected embodiments of the present disclosure. Based on the embodiments of the present disclosure, all other embodiments obtained by those skilled in the art without creative efforts shall fall within the scope of protection of the present disclosure.

It should be noted that similar reference numerals and letters indicate similar items in the following accompanying drawings. Thus, once an item is defined in an accompanying drawing, it is not necessary to further define and explain this item in the subsequent drawings. In addition, the terms, such as “first” and “second”, are used merely to distinguish descriptions, and cannot be understood as indicating or implying relative importance.

In the description of the embodiments of the present disclosure, it should be noted that the orientation or positional relationship indicated by terms “inside”, “outside”, “upper” and the like is based on the orientation or positional relationship shown in the drawings or is the orientation or positional relationship of conventional placement in use of the product of the present disclosure, which is only for convenience of description of the present disclosure and simplification of description rather than indicating or implying that the device or element referred to must have a particular orientation, be constructed and operated in a particular orientation, and which thus is not to be construed as limiting the present disclosure.

### Embodiment I

An asymmetric transmission circular waveguide is provided in this embodiment, which includes a cylindrical outer housing, and a lining medium 1 sleeved in the outer housing. A wall thickness of the lining medium 1 gradually changes in an axial direction. One end of the lining medium 1 with the thinnest wall thickness is a feed port, and another end of the lining medium 1 with the thickest wall thickness is a scattering boundary. Microwave energy is transmitted unidirectionally in a direction from the end of the lining medium with the thinnest wall thickness to the other end of the lining medium with the thickest wall thickness.

The lining medium 1 is formed by rotating a wedge-shaped structure around the center thereof.

The feed port of the lining medium 1 with the thinnest wall thickness is provided with a coupling waveguide.

Both ends of the outer housing are respectively in alignment with both ends of the lining medium 1, the coupling waveguide is fixedly arranged on the outer housing near the feed port of the lining medium 1, and the coupling waveguide is in communication with the feed port of the lining medium 1.

The outer housing and the lining medium 1 each have a length of 260 mm, and the coupling waveguide has a length of 30 mm.

The lining medium 1 is made of a lossless dielectric material with a dielectric constant of 25.

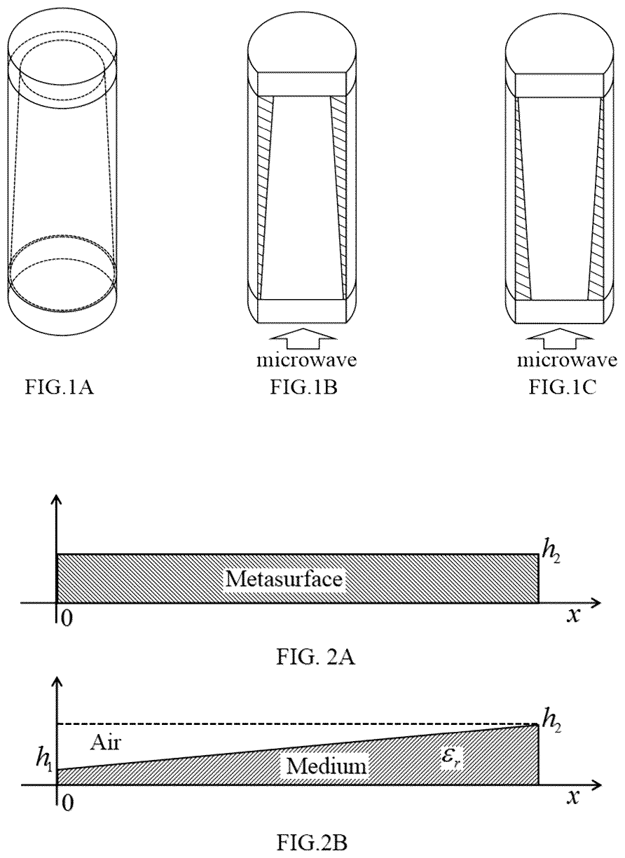

Specifically, as shown in FIG. 1, an asymmetric transmission circular waveguide is designed by rotating the wedge-shaped structure around its center. A structure of a circular waveguide for unidirectional transmission is shown in FIG. 1A, in which the inner irregular cylindrical structure effectively substitutes for a metamaterial with a gradually varying dielectric constant, and the outermost layer is the metallic wall, FIG. 1B illustrates a cross-sectional view of microwave forward propagation within an asymmetric transmission circular waveguide, where the microwave enters from the bottom of the waveguide and propagates in the direction of the gradually increasing dielectric constant of the metamaterial. FIG. 1C illustrates a cross-sectional view of microwave reverse propagation within the asymmetric transmission circular waveguide, where the microwave enters from the bottom of the waveguide and propagates in the direction of the gradually decreasing dielectric constant of the metamaterial.

In many cases, it is difficult to obtain the material with continuously varying dielectric constant. Therefore, by adjusting the volume ratio of a lossless dielectric material to air within the waveguide, a continuous variation of the dielectric constant of the metamaterial is achieved. As shown in FIG. 2, FIG. 2A depicts an ideal metasurface, where the relative dielectric constant gradually increases along the x-direction. FIG. 2B shows a wedge-shaped structure used as a substitute for the metasurface. In the wedge-shaped structure, the proportion of the lossless dielectric material gradually increases along the x-direction, resulting in an increase in the effective relative dielectric constant within this rectangular area as the lossless dielectric material proportion increases. ε, is the dielectric constant of the medium, and the dielectric constant of the air is 1. h₁ is the thickness at the starting end of the wedge-shaped structure, and h₂ is the thickness at the terminal end of the wedge-shaped structure, matching the thickness of the ideal metamaterial.

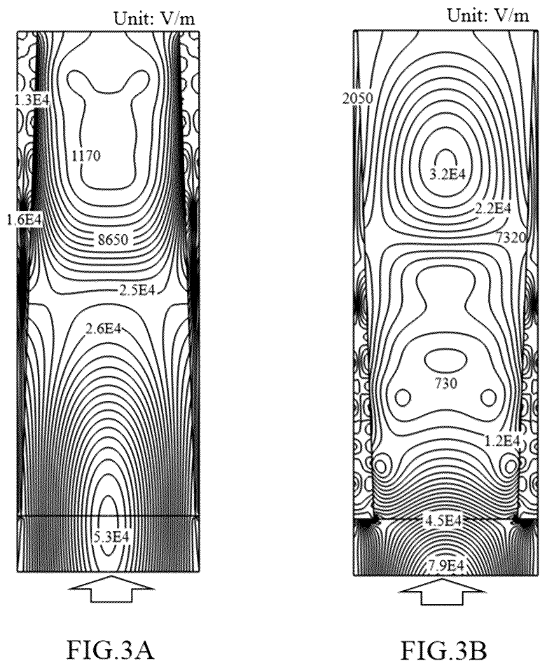

FIG. 3 is a transmission effect diagram of an asymmetric transmission circular waveguide, FIG. 3A is an electric field distribution diagram of forward transmission (where the microwave is fed in from the end with the thinnest thickness of the lining medium, with the other end serving as the scattering boundary), and a microwave transmission efficiency of 96.6%. FIG. 3B is an electric field distribution diagram of reverse transmission (where the microwave is fed in from the end with the thickest thickness of the lining medium, with the other end as the scattering boundary), and a microwave transmission efficiency of 0.1%. The asymmetric transmission circular waveguide needs to be provided with a coupling waveguide at an end thereof during both forward transmission and reverse transmission. As can be seen from the port microwave transmission efficiency, microwave energy can only be fed in from the end with the lower relative dielectric constant of the metamaterial in the asymmetric transmission circular waveguide and transmitted to the other end set as the scattering boundary. It cannot be fed and transmitted from the end with the higher relative dielectric constant, that is, the microwaves are transmitted unidirectionally in the asymmetric transmission circular waveguide.

### Embodiment II

A microwave plasma excitation device based on an asymmetric transmission circular waveguide is provided in this embodiment, which includes the above-mentioned asymmetric transmission circular waveguide, and further includes a cylindrical cavity body 2 which is arranged on one side of a scattering boundary of a lining medium 1 and in mutual communication with the lining medium 1. The cylindrical cavity body 2 is internally provided with a cylindrical tube 3 for accommodating plasma.

The cylindrical cavity body 2 is made of a lossless dielectric material with a dielectric constant of 20, and the cylindrical tube 3 is made of a lossless dielectric material with a dielectric constant of 9.

One end of the cylindrical tube 3 is in alignment with a tail end of an outer housing.

The outer housing is made of metal, and a tube wall of the cylindrical tube 3 and a tube wall of the cylindrical cavity body 2 are made of ceramics.

During operation, the whole system is assembled as follows: a magnetron is connected to a port of a coupler and the microwave plasma excitation device based on the asymmetric transmission circular waveguide, thus coupling the microwave energy into a plasma reaction chamber. During an experiment, argon with a concentration of 99.99% is used, and the gas enters the reaction chamber from an air inlet unit at a bottom of a plasma generator. During an experiment, incident power and reflective power at the port are measured by a microwave power meter, and the inlet gas flow is measured by a flowmeter. The magnetron has a central frequency of 2.45 GHz and a maximum output power of 700 W.

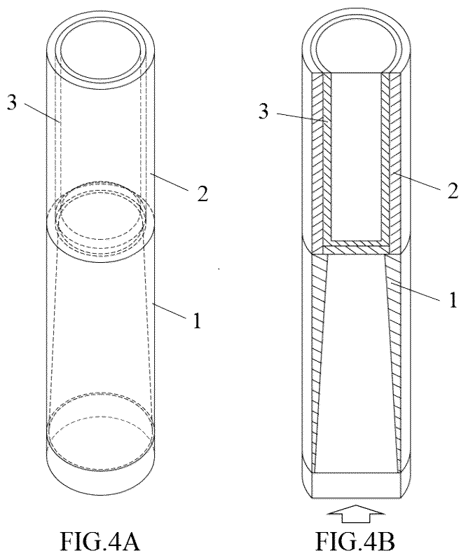

FIG. 4 is a schematic structural diagram of a microwave plasma excitation device based on the asymmetric transmission circular waveguide. The cylindrical cavity body 2 is added at a tail end of a forward transmission waveguide. The lining medium 1 is a lossless dielectric material with a dielectric constant of 25, The cylindrical cavity 2 is a lossless dielectric material with a dielectric constant of 20, and the cylindrical tube 3 is a lossless dielectric material with a dielectric constant of 9. The cylindrical tube 3 made of such material is used to accommodate plasma. The effects are as follows:

The microwave energy of 700 W is input from a coupled waveguide end, an initial temperature of the system is 300 K, and the argon gas is in a tail end tube. The simulation is carried out at pressures of 0.1 torr, 1 torr and 10 torr, respectively. Table 1 shows simulation results at different pressures. It can be seen from Table 1 that at the pressures of 0.1 torr, 1 torr and 10 torr, the port reflection coefficients of argon plasma excited by this device are all less than-10 dB (microwave energy efficiency is 90%), and the microwave energy conversion rates are all above 90%, which shows the high efficiency of this device.

TABLE 1
Table of simulation results under different pressures

| | S parameter at | Efficiency at |
|---|---|---|
| Pressure | steady state | steady state |
| 0.1 torr | −14.409 dB | 98.83% |
| 1 torr | −15.8 dB | 97.4% |
| 10 torr | −24.244 dB | 99.61% |

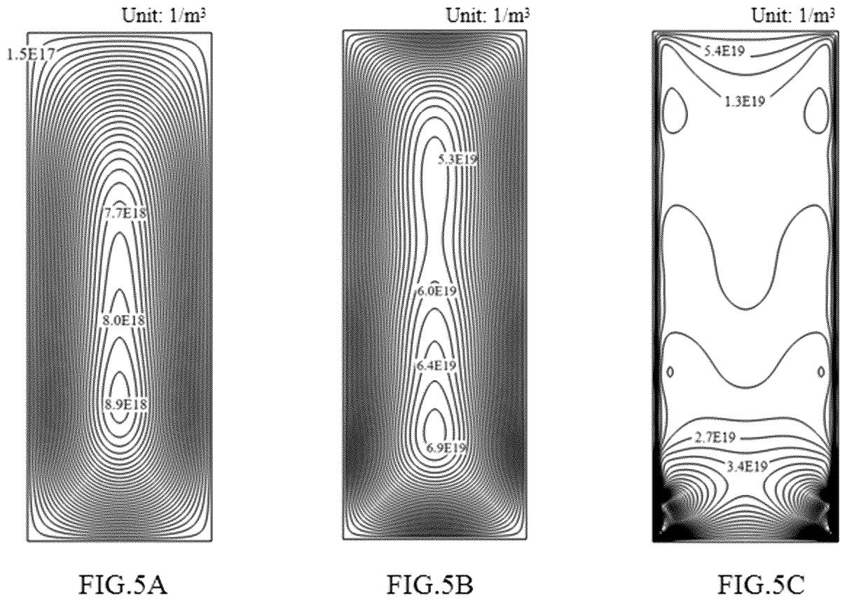

FIG. 5 shows equipotential diagrams of electron density distribution at different pressures, in which FIG. 5A shows the equipotential diagram of electron density distribution at the pressure of 0.1 torr, FIG. 5B shows the equipotential diagram of electron density distribution at the pressure of 1 torr, FIG. 5C shows an electron density distribution diagram at the pressure of 10 torr.

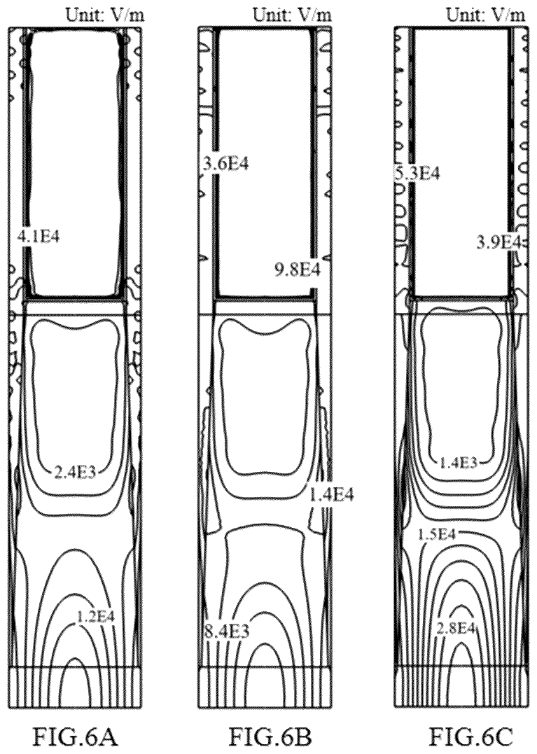

FIG. 6 shows electric field distributions at different pressures, in which FIG. 6A shows the electric field distribution at the pressure of 0.1 torr, FIG. 6B shows the electric field distribution at the pressure of 1 torr, FIG. 6C shows the electric field distribution at the pressure of 10 torr, and all simulation results of all electron density distributions indicate that the plasma has been successfully ignited under these conditions.

In conclusion, the microwave energy utilization rate of the microwave plasma device is improved in the solution provided in the Embodiment II, and the device is universal under various air pressures, with simple structure and easy implementation.

What is claimed is:

1. An asymmetric transmission circular waveguide, comprising a cylindrical outer housing, and a lining medium sleeved in the outer housing, wherein a wall thickness of the lining medium gradually changes in an axial direction, one end of the lining medium with a thinnest wall thickness is a microwave feed port, and an other end of the lining medium with a thickest wall thickness is a scattering boundary; and microwave energy is transmitted unidirectionally in a direction from the end of the lining medium with the thinnest wall thickness to the other end of the lining medium with the thickest wall thickness.

2. The asymmetric transmission circular waveguide according to claim 1, wherein the lining medium (1) is formed by rotating a wedge-shaped structure around a center thereof.

3. The asymmetric transmission circular waveguide according to claim 1, wherein the feed port of the lining medium with the thinnest wall thickness is provided with a coupling waveguide.

4. The asymmetric transmission circular waveguide according to claim 3, wherein both ends of the outer housing are respectively in alignment with both ends of the lining medium, the coupling waveguide is fixedly arranged on the outer housing near the feed port of the lining medium, and the coupling waveguide is in communication with the feed port of the lining medium.

5. The asymmetric transmission circular waveguide according to claim 4, wherein the outer housing and the lining medium each have a length of 260 mm, and the coupling waveguide has a length of 30 mm.

6. The asymmetric transmission circular waveguide according to claim 3, wherein the lining medium is made of a lossless dielectric material with a dielectric constant of 25.

7. A microwave plasma excitation device based on an asymmetric transmission circular waveguide, comprising the asymmetric transmission circular waveguide according to claim 1, and further comprising a cylindrical cavity body which is arranged on one side of a scattering boundary of a lining medium and in mutual communication with the lining medium, wherein the cylindrical cavity body is internally provided with a cylindrical tube for accommodating plasma.

8. The microwave plasma excitation device based on an asymmetric transmission circular waveguide according to claim 7, wherein the cylindrical cavity body is made of a lossless dielectric material with a dielectric constant of 20, and the cylindrical tube is made of a lossless dielectric material with a dielectric constant of 9.

9. The microwave plasma excitation device based on an asymmetric transmission circular waveguide according to claim 7, wherein one end of the cylindrical tube is in alignment with a tail end of the outer housing.

10. The microwave plasma excitation device based on an asymmetric transmission circular waveguide according to claim 7, wherein the outer housing is made of metal, and a tube wall of the cylindrical tube and a tube wall of the cylindrical cavity body are made of ceramics.

11. The asymmetric transmission circular waveguide according to claim 2, wherein the feed port of the lining medium with the thinnest wall thickness is provided with a coupling waveguide.

12. The asymmetric transmission circular waveguide according to claim 11, wherein both ends of the outer housing are respectively in alignment with both ends of the lining medium, the coupling waveguide is fixedly arranged on the outer housing near the feed port of the lining medium, and the coupling waveguide is in communication with the feed port of the lining medium.

13. The asymmetric transmission circular waveguide according to claim 12, wherein the outer housing and the lining medium each have a length of 260 mm, and the coupling waveguide has a length of 30 mm.

14. The asymmetric transmission circular waveguide according to claim 11, wherein the lining medium is made of a lossless dielectric material with a dielectric constant of 25.

15. A microwave plasma excitation device based on an asymmetric transmission circular waveguide, comprising the asymmetric transmission circular waveguide according to claim 2, and further comprising a cylindrical cavity body which is arranged on one side of a scattering boundary of a lining medium and in mutual communication with the lining medium, wherein the cylindrical cavity body is internally provided with a cylindrical tube for accommodating plasma.

16. The microwave plasma excitation device based on an asymmetric transmission circular waveguide according to claim 15, wherein the cylindrical cavity body is made of a lossless dielectric material with a dielectric constant of 20, and the cylindrical tube is made of a lossless dielectric material with a dielectric constant of 9.

17. The microwave plasma excitation device based on an asymmetric transmission circular waveguide according to claim 15, wherein one end of the cylindrical tube is in alignment with a tail end of the outer housing.

18. The microwave plasma excitation device based on an asymmetric transmission circular waveguide according to claim 15, wherein the outer housing is made of metal, and a tube wall of the cylindrical tube and a tube wall of the cylindrical cavity body are made of ceramics.

19. The microwave plasma excitation device based on an asymmetric transmission circular waveguide according to claim 7, wherein the feed port of the lining medium with the thinnest wall thickness is provided with a coupling waveguide.

20. The microwave plasma excitation device based on an asymmetric transmission circular waveguide according to claim 19, wherein the cylindrical cavity body is made of a lossless dielectric material with a dielectric constant of 20, and the cylindrical tube is made of a lossless dielectric material with a dielectric constant of 9.
